(19) United States
(12) Patent Application Publication
(10) Pub. No.: US 2026/0058612 A1
(43) Pub. Date: Feb. 26, 2026

(54) INTERFACING METHODS IN A POWER MANAGEMENT CIRCUIT

(71) Applicant: Qorvo US, Inc., Greensboro, NC (US)

(72) Inventor: Nadim Khlat, Ceret (FR)

(21) Appl. No.: 19/229,586

(22) Filed: Jun. 5, 2025

Related U.S. Application Data
(60) Provisional application No. 63/666,797, filed on Jul. 2, 2024.

(51) Int. Cl. H03F 1/56; H03F 3/21; H03F 3/213

(52) U.S. Cl. CPC H03F 1/56; H03F 3/211; H03F 3/213; H03F 2200/102; H03F 2200/423; H03F 2200/451

(57) ABSTRACT

Interfacing methods in a power management circuit are provided. The power management circuit, which includes a transceiver circuit, a power management integrated circuit (PMIC), and a power amplifier circuit, is configured to generate a modulated voltage to amplify a radio frequency (RF) signal for transmission. Various interfacing methods between the transceiver circuit, the PMIC, and/or the power amplifier circuit are disclosed herein to help the power management circuit to operate with a reduced voltage range to amplify the RF signal across a peak-to-peak power range (a.k.a. minimum to maximum power range). As a result, the power management circuit can operate with improved efficiency to thereby provide improvement in the user experience.

### RELATED APPLICATIONS

This application claims the benefit of U.S. provisional patent application Ser. No. 63/666,797, filed on Jul. 2, 2024, the disclosure of which is hereby incorporated herein by reference in its entirety.

### FIELD OF THE DISCLOSURE

The present disclosure is related to various interfacing methods in a power management circuit operable with reduced voltage range (e.g., a peak-to-peak voltage range).

### BACKGROUND

Mobile communication devices have become increasingly common in current society for providing wireless communication services. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

The redefined user experience requires higher data rates offered by advanced wireless communication technologies such as fifth-generation new-radio (5G-NR). To achieve higher data rates, a mobile communication device is required to amplify a transmission signal to a desired power level to help overcome potential propagation losses and/or interferences. As such, the mobile communication device typically includes a transceiver circuit, a power amplifier circuit, and a power management circuit. Specifically, the transceiver circuit modulates the transmission signal to an intended transmission frequency, the power amplifier circuit amplifies the transmission signal to the desired power level, and the power management circuit supplies an envelope tracking (ET) to the power amplifier circuit. Understandably, to achieve the best-possible efficiency and performance, the power management circuit must adapt the ET voltage in accordance with a modulation bandwidth of the transmission signal.

### SUMMARY

Embodiments of the disclosure relate to interfacing methods in a power management circuit. The power management circuit, which includes a transceiver circuit, a power management integrated circuit (PMIC), and a power amplifier circuit, is configured to generate a modulated voltage to amplify a radio frequency (RF) signal for transmission. Various interfacing methods between the transceiver circuit, the PMIC, and/or the power amplifier circuit are disclosed herein to help the power management circuit to operate with a reduced voltage range to amplify the RF signal across a peak-to-peak power range (a.k.a. minimum to maximum power range). As a result, the power management circuit can operate with improved efficiency to thereby provide improvement in the user experience.

In one aspect, a power management circuit is provided. The power management circuit includes a power amplifier circuit. The power amplifier circuit is configured to amplify an RF signal from an input power to an output power based on a modulated voltage. The power management circuit also includes a PMIC. The PMIC includes a voltage modulation circuit. The voltage modulation circuit is configured to generate the modulated voltage in accordance with a modulated target voltage. The PMIC also includes a load modulation control circuit. The load modulation control circuit is configured to determine a power threshold that is lower than a maximum power threshold of the RF signal but higher than a minimum power threshold of the RF signal. The load modulation control circuit is also configured to generate a load modulation signal to thereby cause the power amplifier circuit to amplify the RF signal based at least on a load modulation when a power level of the RF signal is below the power threshold.

In another aspect, a wireless device is provided. The wireless device includes a power management circuit. The power management circuit includes a power amplifier circuit. The power amplifier circuit is configured to amplify an RF signal from an input power to an output power based on a modulated voltage.

The power management circuit also includes a PMIC. The PMIC includes a voltage modulation circuit. The voltage modulation circuit is configured to generate the modulated voltage in accordance with a modulated target voltage. The PMIC also includes a load modulation control circuit. The load modulation control circuit is configured to determine a power threshold that is lower than a maximum power threshold of the RF signal but higher than a minimum power threshold of the RF signal. The load modulation control circuit is also configured to generate a load modulation signal to thereby cause the power amplifier circuit to amplify the RF signal based at least on a load modulation when a power level of the RF signal is below the power threshold.

In another aspect, a method for interfacing in a power management circuit is provided. The method includes amplifying an RF signal from an input power to an output power based on a modulated voltage. The method also includes generating the modulated voltage in accordance with a modulated target voltage. The method also includes determining a power threshold that is lower than a maximum power threshold of the RF signal but higher than a minimum power threshold of the RF signal. The method also includes generating a load modulation signal to thereby cause the RF signal to be amplified based at least on a load modulation when a power level of the RF signal is below the power threshold.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 is a schematic diagram of an exemplary power management circuit wherein a power management integrated circuit (PMIC) can generate a modulated voltage in accordance with a modulated target voltage for amplifying a radio frequency (RF) signal across a peak-to-peak power range;

FIG. 2 is a diagram providing an exemplary illustration as to how the power management circuit of FIG. 1 is operable to generate the modulated voltage with a reduced voltage range across the peak-to-peak power range of the RF signal in FIG. 1;

FIGS. 3-6 are schematic diagrams illustrating the power management circuit of FIG. 1 configured according to various interfacing embodiments of the present disclosure;

FIG. 7 is a schematic diagram of an exemplary communication device wherein the power management circuit of FIG. 1 can be provided; and

FIG. 8 is a flowchart of an exemplary process for operating the power management circuit of FIG. 1.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to interfacing methods in a power management circuit. The power management circuit, which includes a transceiver circuit, a power management integrated circuit (PMIC), and a power amplifier circuit, is configured to generate a modulated voltage to amplify a radio frequency (RF) signal for transmission. Various interfacing methods between the transceiver circuit, the PMIC, and/or the power amplifier circuit are disclosed herein to help the power management circuit to operate with a reduced voltage range to amplify the RF signal across a peak-to-peak power range (a.k.a. minimum to maximum power range). As a result, the power management circuit can operate with improved efficiency to thereby provide improvement in the user experience.

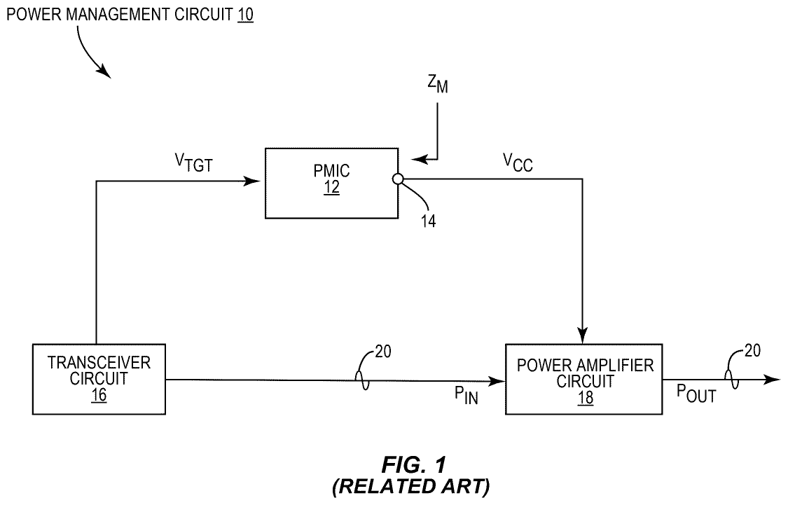

FIG. 1 is a schematic diagram of an exemplary power management circuit 10 wherein a PMIC 12 can generate a modulated voltage V_{CC} (e.g., an envelope tracking voltage) in accordance with a modulated target voltage V_{TGT}. More specifically, the PMIC 12 is configured to generate the modulated voltage V_{CC} at a voltage output 14.

Herein, the power management circuit 10 also includes a transceiver circuit 16 and a power amplifier circuit 18. Specifically, the transceiver circuit 16 is configured to generate an RF signal 20 and the modulated target voltage V_{TGT} that tracks an input power P_{IN} and/or an output power P_{OUT} of the RF signal 20, whereas the power amplifier circuit 18 is configured to amplify the RF signal 20 from the input power P_{IN} to the output power P_{OUT} based on the modulated voltage V_{CC}. In an embodiment, the power amplifier circuit 18 can be configured to present a load line impedance Z_{M} at the voltage output 14.

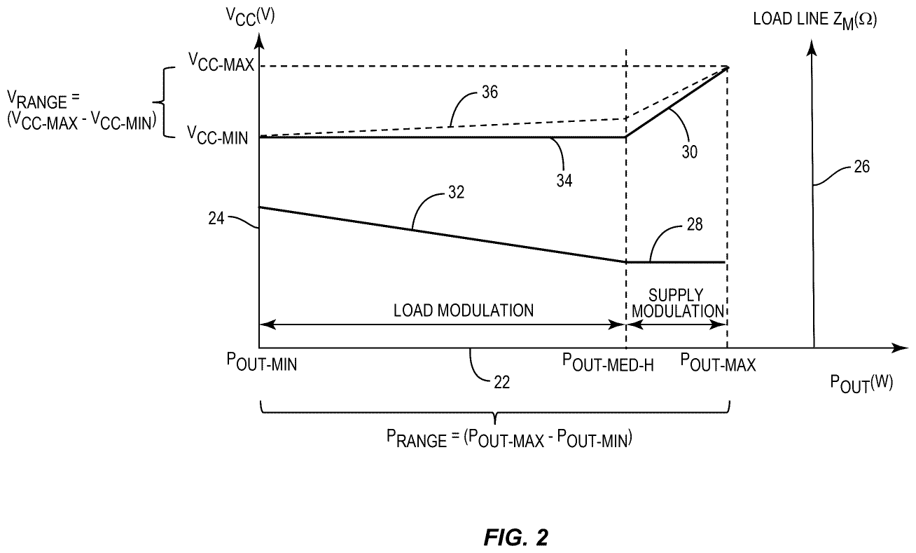

FIG. 2 is a diagram providing an exemplary illustration as to how the power management circuit 10 of FIG. 1 is operable to generate the modulated voltage V_{CC} with a reduced voltage range V_{RANGE} across a peak-to-peak power range P_{RANGE} of the RF signal 20. Common elements between FIGS. 1 and 2 are shown therein with common element numbers and will not be re-described herein.

The plot illustrated herein includes a horizontal axis 22, a first vertical axis 24, and a second vertical axis 26. Specifically, the horizontal axis 22 indicates the output power P_{OUT} of the RF signal 20, the first vertical axis 24 indicates the modulated voltage V_{CC} at the voltage output 14, and the second vertical axis 26 indicates the load line impedance Z_{M} seen at the voltage output 14. In context of the present disclosure, the peak-to-peak power range P_{RANGE} of the RF signal 20 is defined as a difference between a maximum power threshold P_{OUT-MAX} and a minimum power threshold P_{OUT-MIN} of the RF signal 20 (P_{RANGE}=P_{OUT-MAX}−P_{OUT-MIN}). The reduced voltage range V_{RANGE}, on the other hand, is equal to a difference between a maximum voltage level V_{CC-MAX} and a minimum voltage level V_{CC-MIN} (V_{RANGE}=V_{CC-MAX}−V_{CC-MIN}). Understandably, the maximum voltage level V_{CC-MAX} is the modulated voltage V_{CC} required for amplifying the RF signal to the maximum power threshold P_{OUT-MAX}, whereas the minimum voltage level V_{CC-MIN} is the modulated voltage V_{CC} required for amplifying the RF signal to the minimum power threshold P_{OUT-MIN}.

Herein, the power amplifier circuit 18 is configured to operate in a compression mode. In this regard, the power management circuit 10 can be configured to first determine a power threshold P_{OUT-MED-H} that is lower than the maximum power threshold P_{OUT-MAX} but higher than the minimum power threshold P_{OUT-MIN} of the RF signal 20 (P_{OUT-MIN}<P_{OUT-MED-H}<P_{OUT-MAX}). In a non-limiting example, the power threshold P_{OUT-MED-H} can be 6 dB below the maximum power threshold P_{OUT-MAX} of the RF signal 20 (P_{OUT-MED-H}=P_{OUT-MAX}−6 dB).

When the instantaneous power level P_{OUT} of the RF signal 20 is higher than or equal to the power threshold P_{OUT-MED-H} (P_{OUT}≥P_{OUT-MED-H}), the power management circuit 10 is configured to generate the modulated voltage V_{CC} based on a supply modulation. Herein, the supply modulation indicates that the power management circuit 10 will maintain the load line impedance Z_{M} (as illustrated by line 28) and increase the modulated voltage V_{CC} (as illustrated by line 30). In contrast, when the instantaneous power level P_{OUT} of the RF signal 20 is below the power threshold P_{OUT-MED-H} (P_{OUT}<P_{OUT-MED-H}), the power management circuit 10 may be configured according to one of the following two options.

In a first option, the power management circuit 10 can generate the modulated voltage V_{CC} based on a load modulation. Herein, the load modulation indicates that the power management circuit 10 will reduce the load line impedance Z_{M} (as illustrated by line 32) and maintain the modulated voltage V_{CC} (as illustrated by line 34) at the minimum voltage level V_{CC-MIN}. In a second option, the power management circuit 10 can generate the modulated voltage V_{CC} based on a combination of the load modulation and the supply modulation. Specifically, the power management circuit 10 may slightly increase the modulated voltage V_{CC} (as illustrated by a dotted line 36) by performing both the load modulation and the supply modulation.

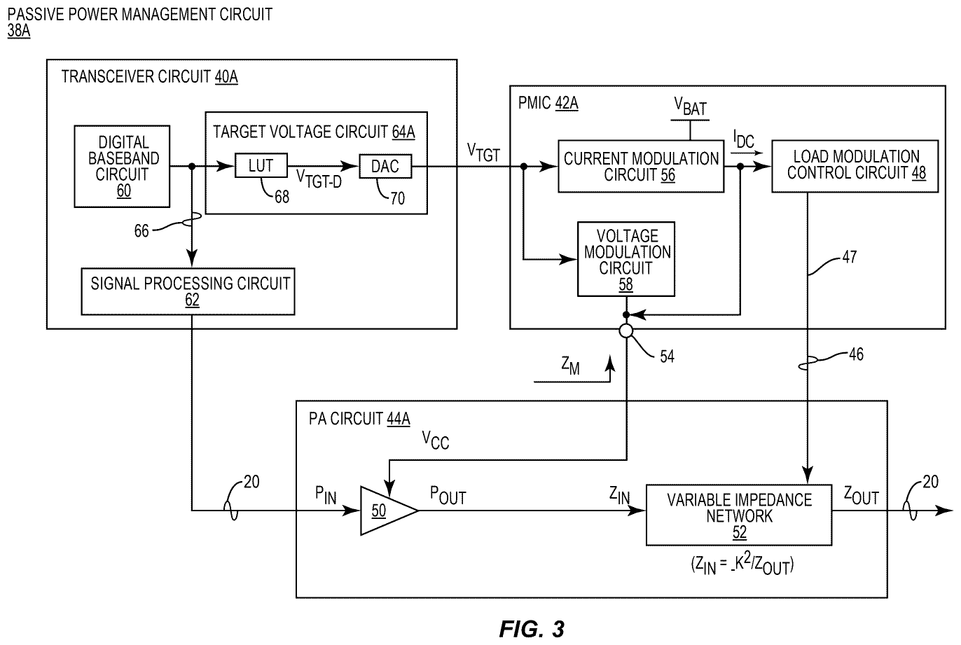

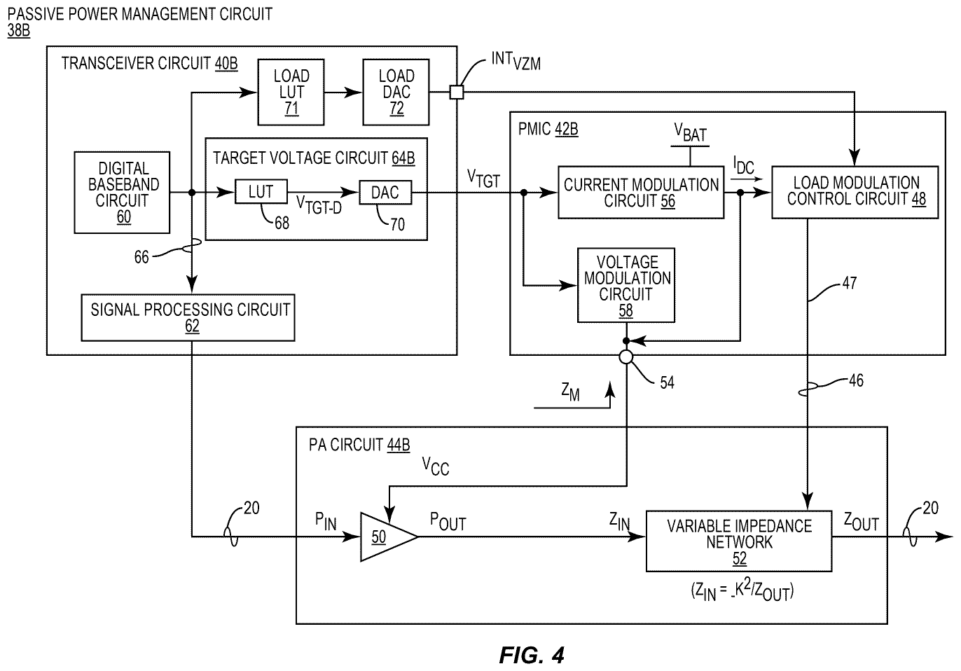

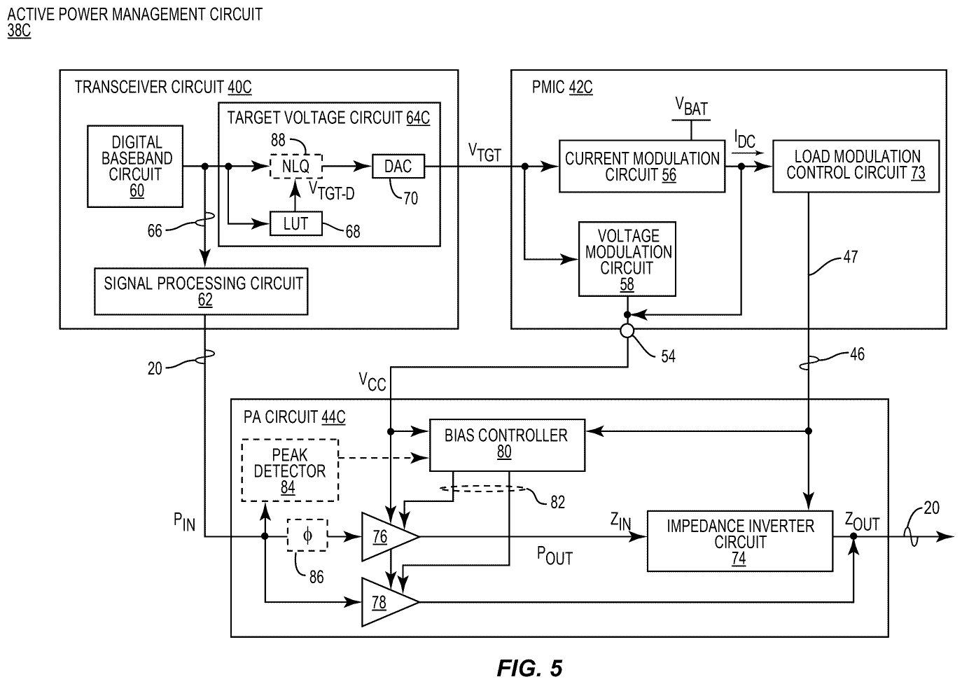

FIGS. 3-6 are schematic diagrams illustrating the power management circuit 10 of FIG. 1 configured according to various interfacing embodiments of the present disclosure. Specifically, FIGS. 3 and 4 each illustrate a passive power management circuit, whereas FIGS. 4 and 5 each illustrate an active power management circuit. Common elements between FIGS. 1-6 are shown therein with common element numbers and will not be re-described herein.

FIG. 3 is a schematic diagram of an exemplary passive power management circuit 38A, wherein a transceiver circuit 40A, a PMIC 42A, and a power amplifier circuit 44A are configured to replace the transceiver circuit 16, the PMIC 12, and the power amplifier circuit 18 in the power management circuit 10 of FIG. 1, respectively. In this regard, the transceiver circuit 40A, the PMIC 42A, and the power amplifier circuit 44A are functionally equivalent to the transceiver circuit 16, the PMIC 12, and the power amplifier circuit 18.

Herein, the transceiver circuit 40A is configured to generate the RF signal 20 and the modulated target voltage V_{TGT} that tracks the output power P_{OUT} of the RF signal 20, the PMIC 42A is configured to generate the modulated voltage V_{CC} in accordance with the modulated target voltage V_{TGT}, and the power amplifier circuit 44A is configured to amplify the RF signal 20 from the input power P_{IN} to the output power P_{OUT} based on the modulated voltage V_{CC}. As described below, the PMIC 42A is further configured to provide a load modulation signal 46 to the power amplifier circuit 44A to thereby indicate how the power amplifier circuit 44A should perform the load modulation and/or the supply modulation (as illustrated in FIG. 2) when the instantaneous output power P_{OUT} of the RF signal 20 is below the power threshold P_{OUT-MED-H}. In a non-limiting example, the load modulation signal 46 can be provided over a load modulation control (LMC) analog control line 47.

In an embodiment, the PMIC 42A can include a load modulation control circuit 48. Herein, the load modulation control circuit 48 is configured to determine the power threshold P_{OUT-MED-H} that is lower than the maximum power threshold P_{OUT-MAX} of the RF signal 20 but higher than the minimum power threshold P_{OUT-MIN} of the RF signal 20. Accordingly, the load modulation control circuit 48 can generate the load modulation signal 46 to thereby cause the power amplifier circuit 44A to amplify the RF signal 20 based on the load modulation and/or the supply modulation when the instantaneous power level P_{OUT} of the RF signal 20 is below the power threshold P_{OUT-MED-H}.

In an embodiment, the power amplifier circuit 44A can include an amplifier 50 coupled in series to a variable impedance network 52. The amplifier 50 is configured to amplify the RF signal 20 from the input power P_{IN} to the output power P_{OUT} based on the modulated voltage V_{CC}. The variable impedance network 52, which can be an acoustic-based impedance network, is configured to transform the load line impedance Z_{M} at a voltage output 54 in response to receiving the load modulation signal 46. Because the acoustic-based impedance network is passive in nature, the passive power management circuit 38A is therefore referred to as being passive for the sake of distinction despite such active components/circuits as the amplifier 50.

In a non-limiting example, the variable impedance network 52 can be a variable impedance inverter network configured to influence the load line impedance Z_{M} in accordance with the equation (Eq. 1) below.

Z_{IN}=−k²/Z_{OUT} (eq. 1)

In the equation (Eq. 1), Z_{IN} represents an input impedance seen by the variable impedance network 52, K represents a tunable gain factor of the variable impedance network 52, and Z_{OUT} represents an output impedance seen by the variable impedance network 52 (e.g., impedance of a downstream circuit). In an embodiment, the tunable gain factor K can be electrically tuned in accordance with the output impedance Z_{OUT} to thereby change the input impedance Z_{IN}. Notably, the load line impedance Z_{M} can be a function of the input impedance Z_{IN}. Accordingly, by electrically tuning the input impedance Z_{IN}, it is thus possible to influence the load line impedance Z_{M}. In a non-limiting example, the variable impedance network 52 can be electrically tuned as described in U.S. patent application Ser. No. 18/747,555, entitled “ACOUSTIC RESONATOR FILTER STRUCTURE WITH TUNABLE SHUNT COUPLED RESONATOR FILTER.”

The PMIC 42A includes a current modulation circuit 56 and a voltage modulation circuit 58. The current modulation circuit 56 is configured to generate a low-frequency current I_{DC} as a function of a battery voltage V_{BAT}. The current modulation circuit 56 is also configured to provide the low-frequency current I_{DC} to the load modulation control circuit 48 and the voltage output 54. The voltage modulation circuit 58, on the other hand, is configured to generate the modulated voltage V_{CC} based on the modulated target voltage V_{TGT} and provide the modulated voltage V_{CC} to the amplifier 50 for amplifying the RF signal 20.

The transceiver circuit 40A can be configured to include a digital baseband circuit 60, a signal processing circuit 62, and a target voltage circuit 64A. The digital baseband circuit 60 is configured to generate a digital signal 66, which the signal processing circuit 62 will convert into the RF signal 20. The target voltage circuit 64A may include a lookup table (LUT) 68 and a digital-to-analog converter (DAC) 70. In an embodiment, the LUT 68 is configured to generate a digital target voltage V_{TGT-D} that tracks the input power P_{IN} and/or the output power P_{OUT} of the digital signal 66. The DAC 70, on the other hand, is configured to convert the digital target voltage V_{TGT-D} into the modulated target voltage V_{TGT.}

FIG. 4 is a schematic diagram of an exemplary passive power management circuit 38B, wherein a transceiver circuit 40B, a PMIC 42B, and a power amplifier circuit 44B are configured to replace the transceiver circuit 16, the PMIC 12, and the power amplifier circuit 18 in the power management circuit 10 of FIG. 1, respectively. In this regard, the transceiver circuit 40B, the PMIC 42B, and the power amplifier circuit 44B are functionally equivalent to the transceiver circuit 16, the PMIC 12, and the power amplifier circuit 18.

Herein, the PMIC 42B and the power amplifier circuit 44B may be identical or functionally equivalent to the PMIC 42A and the power amplifier circuit 44A in FIG. 3, respectively. The transceiver circuit 40B, however, can be further configured to further include a target voltage circuit 64B, a load LUT 71, and a load DAC 72. The target voltage circuit 64B may be identical or functionally equivalent to the target voltage circuit 64A in FIG. 3. In essence, the load LUT 71 may be configured to correlate the load line impedance Z_{M} with the input power P_{IN} and/or the output power P_{OUT} of the digital signal 66. In this regard, the load modulation control circuit 48 will be interfacing to the transceiver circuit 40B via a digital voltage interface INT_{VZM} to thereby receive an expected value of the load line impedance Z_{M} that is required for the load modulation. Like the passive power management circuit 38A in FIG. 3, the passive power management circuit 38B is also referred to as being passive because the acoustic-based impedance network is passive in nature.

FIG. 5 is a schematic diagram of an exemplary active power management circuit 38C, wherein a transceiver circuit 40C, a PMIC 42C, and a power amplifier circuit 44C are configured to replace the transceiver circuit 16, the PMIC 12, and the power amplifier circuit 18 in the power management circuit 10 of FIG. 1, respectively. In this regard, the transceiver circuit 40C, the PMIC 42C, and the power amplifier circuit 44C are functionally equivalent to the transceiver circuit 16, the PMIC 12, and the power amplifier circuit 18.

Herein, the PMIC 42C includes a load modulation control circuit 73, which may be identical or different from the load modulation control circuit 48 in FIGS. 3 and 4. The load modulation control circuit 73 is configured to determine the power threshold P_{OUT-MED-H} that is lower than the maximum power threshold P_{OUT-MAX} of the RF signal 20 but higher than the minimum power threshold P_{OUT-MIN} of the RF signal 20. Accordingly, the load modulation control circuit 73 can generate the load modulation signal 46 to thereby cause the power amplifier circuit 44C to amplify the RF signal 20 based on the load modulation and/or the supply modulation when the instantaneous power level P_{OUT} of the RF signal 20 is below the power threshold P_{OUT-MED-H}.

The power amplifier circuit 44C, on the other hand, can include an impedance inverter circuit 74, a first amplifier 76, a second amplifier 78, and a bias controller 80. Because the impedance inverter circuit 74 is active in nature, the active power management circuit 38C is therefore referred to as being active for the sake of distinction from the passive power management circuit 38A of FIG. 3 and the passive power management circuit 38B of FIG. 4, despite existence of such active components/circuits as the first amplifier 76, the second amplifier 78, and the bias controller 80. In an embodiment, the impedance inverter circuit 74 is coupled to the load modulation control circuit 73 to receive the load modulation signal 46. The first amplifier 76 and the second amplifier 78 are each coupled to the voltage modulation circuit 58 and the impedance inverter circuit 74.

Notably, the first amplifier 76 is active all the time when the instantaneous output power P_{OUT} of the RF signal 20 is below the power threshold P_{OUT-MED-H}, whereas the second amplifier 78 is only activated as needed when the instantaneous output power P_{OUT} of the RF signal 20 is below the power threshold P_{OUT-MED-H}. In this regard, the bias controller 80 can be configured to always bias the first amplifier 76 in response to receiving the load modulation signal 46 that indicates the load modulation (corresponding to the line 34 in FIG. 2), and only bias the second amplifier 78 in response to receiving the load modulation signal 46 that indicates the combination of load modulation and supply modulation (corresponding to the line 36 in FIG. 2). Notably, by activating the second amplifier 78, it is possible to change the slope of the load modulation between the lines 34 and 36. In a non-limiting example, the bias controller 80 may bias the first amplifier 76 and the second amplifier 78 via a bias signal 82.

In an embodiment, the power amplifier circuit 44C can be configured to further include a peak detector 84. Herein, the peak detector 84 is coupled to the transceiver circuit 40C to receive the modulated target voltage V_{TGT}. Accordingly, the peak detector 84 can help the bias controller 80 to control the second amplifier 78 based on the input power P_{IN} of the RF signal 20. In another embodiment, the power amplifier circuit 44C can further include a phase adjuster 86, which is coupled to the first amplifier 76.

The transceiver circuit 40C may also include a target voltage circuit 64C. Herein, the target voltage circuit 64C can further include a non-linear equalizer 88. In an embodiment, the non-linear equalizer 88 can be configured to estimate an unwanted ripple in the modulated voltage V_{CC} based on, for example, the modulated voltage V_{CC} and the input power P_{IN} of the RF signal 20. Accordingly, the non-linear equalizer 88 may apply an equalization filter onto the digital target voltage V_{TGT-D} to help overcome the unwanted ripple in the modulate voltage V_{CC}.

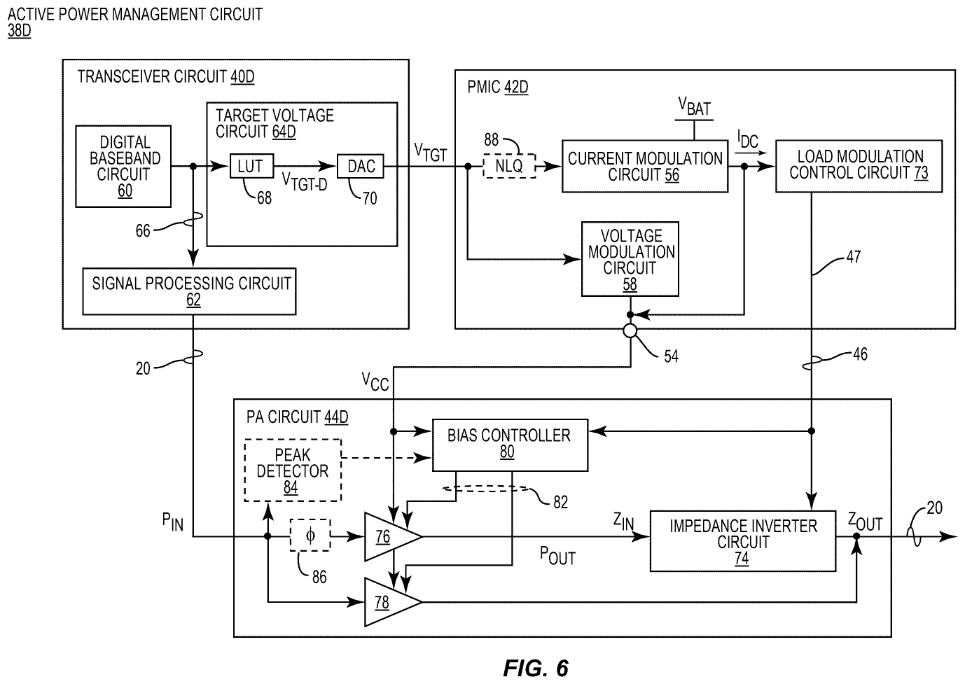

FIG. 6 is a schematic diagram of an exemplary active power management circuit 38D, wherein a transceiver circuit 40D, a PMIC 42D, and a power amplifier circuit 44D are configured to replace the transceiver circuit 16, the PMIC 12, and the power amplifier circuit 18 in the power management circuit 10 of FIG. 1, respectively. In this regard, the transceiver circuit 40D, the PMIC 42D, and the power amplifier circuit 44D are functionally equivalent to the transceiver circuit 16, the PMIC 12, and the power amplifier circuit 18.

Specifically, the non-linear equalizer 88 may be moved from the transceiver circuit 40C in FIG. 5 into the PMIC 42D herein. Understandably, by adding the non-linear equalizer 88 into the PMIC 42D, it is possible to compensate for a ripple in the modulated voltage V_{CC}, which may be caused by the load line impedance Z_{M} that can cause a load current in the power amplifier circuit 44D to be non-linearly related to the modulated target voltage V_{TGT}.

One important aspect in the active power management circuit 38C and the active power management circuit 38D is that both the first amplifier 76 and the second amplifier 78 (when activated) will each deliver one-half (½) of the input power P_{IN} and/or the output power P_{OUT}. As a result, both the first amplifier 76 and the second amplifier 78 will operate in the compression mode.

Accordingly, the loss introduced by the impedance inverter circuit 74 will only affect the first amplifier 76.

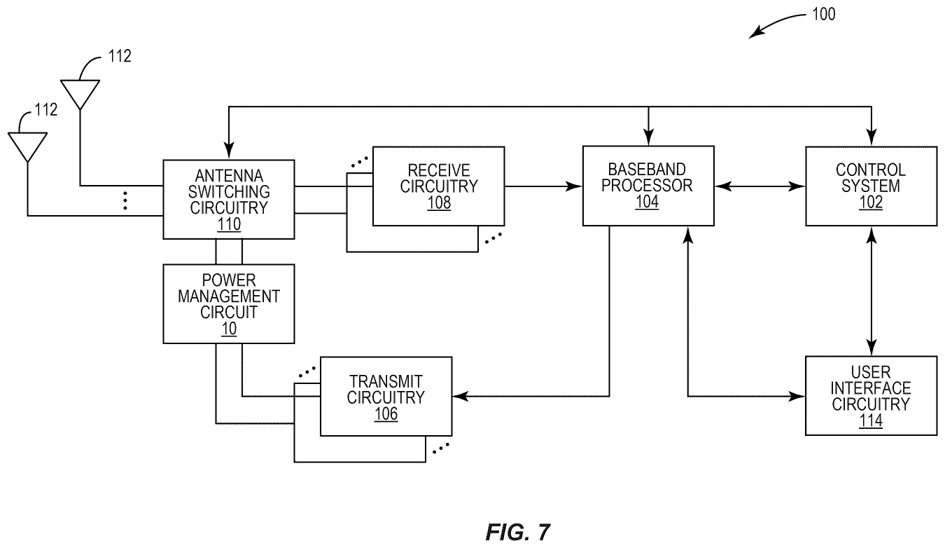

The power management circuit 10 of FIG. 1, which can include the passive power management circuit 38A of FIG. 3, the passive power management circuit 38B of FIG. 4, the active power management circuit 38C of FIG. 5, and the active power management circuit 38D of FIG. 6, can be provided in a communication device to support the embodiments described above. In this regard, FIG. 7 is a schematic diagram of an exemplary communication device 100 wherein the power management circuit 10 of FIG. 1 can be provided.

Herein, the communication device 100 can be any type of communication devices, such as mobile terminals, smart watches, tablets, computers, navigation devices, access points, base stations (e.g., eNB, gNB, etc.), and like wireless communication devices that support wireless communications, such as cellular, wireless local area network (WLAN), Ultra-wideband (UWB), Bluetooth, and near-field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor, an embedded memory circuit, and a communication bus interface. The receive circuitry 108 receives radio frequency signals via the antennas 112 and through the antenna switching circuitry 110 from one or more base stations. A low-noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converters (ADCs).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application-specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 112 through the antenna switching circuitry 110. The multiple antennas 112 and the replicated transmit 106 and receive circuitry 108 may provide spatial diversity. Modulation and processing details will be understood by those skilled in the art.

In an embodiment, the transmit circuitry 106 and the receive circuitry 108 can function as a transceiver circuit. Accordingly, power management circuit 10 can be provided between the transmit circuitry 106 and the antenna switching circuitry 110.

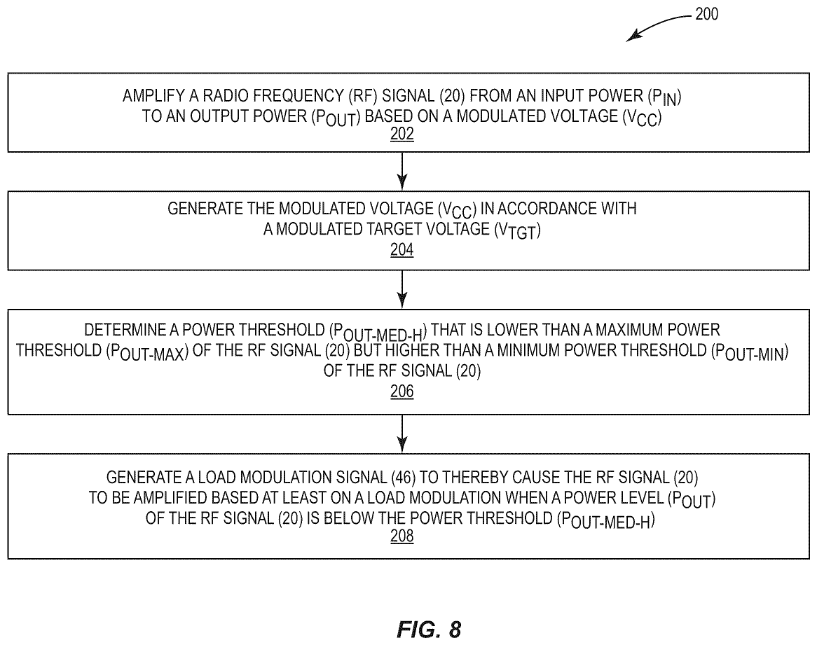

In an embodiment, the power management circuit 10 of FIG. 1 can be operated in accordance with a process. In this regard, FIG. 8 is a flowchart of an exemplary process 200 for operating the power management circuit 10 of FIG. 1.

Herein, the process 200 includes amplifying the RF signal 20 from the input power P_{IN} to the output power P_{OUT} based on the modulated voltage V_{CC} (step 202). The process 200 also includes generating the modulated voltage V_{CC} in accordance with the modulated target voltage V_{TGT} (step 204). The process 200 also includes determining the power threshold P_{OUT-MED-H} that is lower than the maximum power threshold P_{OUT-MAX} of the RF signal 20 but higher than the minimum power threshold P_{OUT-MIN} of the RF signal 20 (step 206). The process 200 also includes generating the load modulation signal 46 to thereby cause the RF signal 20 to be amplified based at least on the load modulation when the power level P_{OUT} of the RF signal 20 is below the power threshold P_{OUT-MED-H} (step 208).

Those skilled in the art will recognize improvements and modifications to the preferred embodiments of the present disclosure. All such improvements and modifications are considered within the scope of the concepts disclosed herein and the claims that follow.

What is claimed is:

1. A power management circuit comprising:
a power amplifier circuit configured to amplify a radio frequency (RF) signal from an input power to an output power based on a modulated voltage; and
a power management integrated circuit (PMIC) comprising:
a voltage modulation circuit configured to generate the modulated voltage in accordance with a modulated target voltage; and
a load modulation control circuit configured to:
determine a power threshold that is lower than a maximum power threshold of the RF signal but higher than a minimum power threshold of the RF signal; and
generate a load modulation signal to thereby cause the power amplifier circuit to amplify the RF signal based at least on a load modulation when a power level of the RF signal is below the power threshold.

2. The power management circuit of claim 1, wherein the modulated voltage is an envelope tracking (ET) voltage.

3. The power management circuit of claim 1, wherein the load modulation control circuit is further configured to cause the voltage modulation circuit to maintain the modulated voltage below a maximum voltage level of the RF signal.

4. The power management circuit of claim 1, wherein the load modulation control circuit is further configured to cause the voltage modulation circuit to increase the modulated voltage toward a maximum voltage level of the RF signal.

5. The power management circuit of claim 1, further comprising a transceiver circuit configured to generate the RF signal and the modulated target voltage.

6. The power management circuit of claim 5, wherein the power amplifier circuit is a passive power amplifier circuit and comprises a variable impedance network coupled to the load modulation control circuit and configured to operate based at least on the load modulation in response to receiving the load modulation signal.

7. The power management circuit of claim 6, wherein the variable impedance network is electrically tuned to present a load line impedance at a voltage output of the PMIC to thereby cause the power amplifier circuit to amplify the RF signal based on the load modulation.

8. The power management circuit of claim 7, wherein the variable impedance network is a variable impedance inverter network that can be tuned as expressed as: Z_{IN}=−K²/Z_{OUT}, wherein:
Z_{IN} represents an input impedance of the variable impedance inverter network that can influence the load line impedance;
Z_{OUT} represents an output impedance of the variable impedance inverter network; and
K represents a tunable gain factor of the variable impedance inverter network.

9. The power management circuit of claim 7, wherein the transceiver circuit comprises a load lookup table (LUT) coupled to the load modulation control circuit and configured to indicate to the load modulation control circuit an expected value of the load line impedance required for the load modulation.

10. The power management circuit of claim 1, wherein the power amplifier circuit is an active power amplifier circuit and comprises:
an impedance inverter circuit coupled to the load modulation control circuit to receive the load modulation signal;
a first amplifier and a second amplifier each coupled to the voltage modulation circuit and the impedance inverter circuit; and
a bias controller coupled to the voltage modulation circuit and the load modulation control circuit and configured to always bias the first amplifier in response to receiving the load modulation signal.

11. The power management circuit of claim 10, wherein the bias controller is further configured to bias the second amplifier in response to receiving the load modulation signal to thereby change a slope of the load modulation.

12. The power management circuit of claim 11, wherein the power management circuit further comprises a peak detector configured to help the bias controller to control the second amplifier based on the input power of the RF signal.

13. A wireless device comprising a power management circuit, the power management circuit comprising:
a power amplifier circuit configured to amplify a radio frequency (RF) signal from an input power to an output power based on a modulated voltage; and
a power management integrated circuit (PMIC) comprising:
a voltage modulation circuit configured to generate the modulated voltage in accordance with a modulated target voltage; and
a load modulation control circuit configured to:
determine a power threshold that is lower than a maximum power threshold of the RF signal but higher than a minimum power threshold of the RF signal; and
generate a load modulation signal to thereby cause the power amplifier circuit to amplify the RF signal based at least on a load modulation when a power level of the RF signal is below the power threshold.

14. The wireless device of claim 13, wherein the power management circuit further comprises a transceiver circuit configured to generate the RF signal and the modulated target voltage.

15. The wireless device of claim 14, wherein the power amplifier circuit is a passive power amplifier circuit and comprises a variable impedance network coupled to the load modulation control circuit and configured to operate based at least on the load modulation in response to receiving the load modulation signal.

16. The wireless device of claim 15, wherein the variable impedance network is electrically tuned to present a load line impedance at a voltage output of the PMIC to thereby cause the power amplifier circuit to amplify the RF signal based on the load modulation.

17. The wireless device of claim 16, wherein the transceiver circuit comprises a load lookup table (LUT) coupled to the load modulation control circuit and configured to indicate to the load modulation control circuit an expected value of the load line impedance required for the load modulation.

18. The wireless device of claim 13, wherein the power amplifier circuit is an active power amplifier circuit and comprises:
an impedance inverter circuit coupled to the load modulation control circuit to receive the load modulation signal;
a first amplifier and a second amplifier each coupled to the voltage modulation circuit and the impedance inverter circuit; and
a bias controller coupled to the voltage modulation circuit and the load modulation control circuit and configured to always bias the first amplifier in response to receiving the load modulation signal.

19. The wireless device of claim 18, wherein the bias controller is further configured to bias the second amplifier in response to receiving the load modulation signal to thereby change a slope of the load modulation.

20. A method for interfacing in a power management circuit comprising:
amplifying a radio frequency (RF) signal from an input power to an output power based on a modulated voltage;
generating the modulated voltage in accordance with a modulated target voltage;
determining a power threshold that is lower than a maximum power threshold of the RF signal but higher than a minimum power threshold of the RF signal; and
generating a load modulation signal to thereby cause the RF signal to be amplified based at least on a load modulation when a power level of the RF signal is below the power threshold.
